(19) United States
(12) Patent Application Publication
(10) Pub. No.: US 2025/0089335 A1
(43) Pub. Date: Mar. 13, 2025

(54) SEMICONDUCTOR DEVICE

(71) Applicant: Sumitomo Electric Device Innovations, Inc., Yokohama-shi (JP)

(72) Inventors: Yuji KIMOTO, Yokohama-shi (JP); Hiroaki MARUYAMA, Yokohama-shi (JP)

(73) Assignee: Sumitomo Electric Device Innovations, Inc., Yokohama-shi (JP)

(21) Appl. No.: 18/826,816

(22) Filed: Sep. 6, 2024

(30) Foreign Application Priority Data
Sep. 8, 2023 (JP) 2023-146217

(51) Int. Cl. H01L 29/417; H01L 23/50; H01L 27/095; H01L 29/20; H01L 29/778

(52) U.S. Cl. CPC H10D 64/254; H01L 23/50; H10D 30/475; H10D 62/8503; H10D 84/86

(57) ABSTRACT

A semiconductor device includes a substrate having a main surface and a back surface, and first and second transistors. A first gate wiring is provided on the main surface a disposed in a first source electrode of the first transistor when viewed from a direction, and is electrically connected to a first gate electrode thereof. The second source electrode is interposed between a second gate electrode of the second transistor and a first gate wiring. A back metal layer is provided on the back surface and is electrically connected to the first source electrode and a second source electrode of the second transistor through a first via hole and a second via hole which overlap the first source electrode and the second source electrode, respectively, when viewed in a thickness direction of the substrate.

### CROSS REFERENCE TO RELATED APPLICATION

The application claims priority based on Japanese Patent Application No. 2023-146217 filed on Sep. 8, 2023, and the entire contents of the Japanese patent application are incorporated herein by reference.

### FIELD

A certain aspect of the embodiments is related to a semiconductor device.

### BACKGROUND

In a field effect transistor (FET) having a finger-shaped source electrode, a finger-shaped gate electrode, and a finger-shaped drain electrode, it is known that a plurality of unit FETs having a source electrode, a gate electrode, and a drain electrode are arranged in the extending direction of the electrodes (for example, Patent Document 1: Japanese Laid-Open Patent Publication No. 2002-299351, Patent Document 2: U.S. Patent Application Publication No. 2017/0271329, and Patent Document 3: Japanese Laid-Open Patent Publication No. 2022-135899).

### SUMMARY

A semiconductor device according to the present disclosure includes a substrate having a main surface and a back surface facing the main surface, a first transistor provided on the main surface, the first transistor including a first source electrode, a first drain electrode, and a first gate electrode interposed between the first source electrode and the first drain electrode in a first direction, a second transistor provided on the main surface, the second transistor including a second source electrode interposed in the first source electrode as viewed from a second direction intersecting the first direction, a second drain electrode electrically connected to the first drain electrode, and a second gate electrode interposed between the second source electrode and the second drain electrode in the first direction, a first gate wiring provided on the main surface disposed in the first source electrode when viewed from the second direction, and electrically connected to the first gate electrode, the second source electrode being interposed between the second gate electrode and the first gate wiring, and a back metal layer provided on the back surface and electrically connected to the first source electrode and the second source electrode through a first via hole and a second via hole which overlap the first source electrode and the second source electrode, respectively, when viewed in the thickness direction of the substrate.

### BRIEF DESCRIPTION OF THE DRAWINGS

FIG. 1 is a plan view of a semiconductor device according to a first embodiment.

FIG. 2 is a cross-sectional view taken along a line A-A in FIG. 1.

FIG. 3 is a cross-sectional view taken along a line B-B in FIG. 1.

FIG. 4 is a plan view of a semiconductor device according to a first comparative example.

FIG. 5 is a plan view of a semiconductor device according to a second embodiment.

FIG. 6 is a cross-sectional view taken along a line A-A in FIG. 5.

FIG. 7 is a plan view of a semiconductor device according to a first modification of the second embodiment.

FIG. 8 is a plan view of a semiconductor device according to a second modification of the second embodiment.

FIG. 9 is a cross-sectional view taken along a line A-A in FIG. 8.

FIG. 10 is a cross-sectional view taken along a line B-B in FIG. 8.

FIG. 11 is a plan view of a semiconductor device according to a third embodiment.

FIG. 12 is a cross-sectional view taken along a line A-A in FIG. 11.

FIG. 13 is a cross-sectional view taken along a line B-B in FIG. 11.

FIG. 14 is a plan view of a semiconductor device according to a first modification of the third embodiment.

FIG. 15 is an enlarged plan view of a semiconductor device according to a second modification of the third embodiment.

FIG. 16 is a cross-sectional view taken along a line A-A in FIG. 15.

FIG. 17 is a cross-sectional view taken along a line B-B in FIG. 15.

FIG. 18 is a plan view of a semiconductor device according to a third modification of the third embodiment, and is an enlarged plan view of transistors 35a and 35c.

FIG. 19 is a cross-sectional view taken along a line A-A in FIG. 18.

### DETAILED DESCRIPTION

By arranging a plurality of unit FETs in the extending direction of the electrode, the width of the gate electrode in the unit FET can be shortened. Therefore, the gate resistance can be suppressed. However, the source inductance is increased or the gate-source parasitic capacitance is increased. This degrades the characteristics.

The present disclosure has been made in view of the above problems, and an object thereof is to suppress deterioration of characteristics.

### Description of Embodiments of the Present Disclosure

First, the contents of the embodiments of the present disclosure will be enumerated and described.
(1) A semiconductor device includes a substrate having a main surface and a back surface facing the main surface, a first transistor provided on the main surface, the first transistor including a first source electrode, a first drain electrode, and a first gate electrode interposed between the first source electrode and the first drain electrode in a first direction, a second transistor provided on the main surface, the second transistor including a second source electrode interposed in the first source electrode as viewed from a second direction intersecting the first direction, a second drain electrode electrically connected to the first drain electrode, and a second gate electrode interposed between the second source electrode and the second drain electrode in the first direction, a first gate wiring provided on the main surface disposed in the first source electrode when viewed from the second direction, and electrically connected to the first gate electrode, the second source electrode being interposed between the second gate electrode and the first gate wiring, and a back metal layer provided on the back surface and electrically connected to the first source electrode and the second source electrode through a first via hole and a second via hole which overlap the first source electrode and the second source electrode, respectively, when viewed in the thickness direction of the substrate. This makes it possible to equalize the source inductances of the first and second transistors and to equalize the high-frequency characteristics, and therefore to equalize the high-frequency characteristics of the semiconductor device.
(2) In the above (1), the conductor device may further include a third transistor provided on the main surface, the third transistor including a third source electrode interposed in the first source electrode as viewed in the second direction, overlapping the second source electrode, and electrically connected to the first source electrode and the second source electrode, a third drain electrode electrically connected to the first drain electrode and the second drain electrode, and a third gate electrode interposed between the third source electrode and the third drain electrode in the first direction. This allows three or more transistors to be arranged in the second direction.
(3) In the above (2), the back metal layer may be electrically connected to the third source electrode through a third via hole which overlaps the third source electrode when viewed in the thickness direction. This makes it possible to make the source inductances of the first to third transistors uniform, and to make the high-frequency characteristics of the semiconductor device more uniform.
(4) In any one of the above (1) to (3), the semiconductor device may further include a fourth transistor provided on the main surface, the fourth transistor including a fourth source electrode disposed in the first source electrode when viewed from the second direction, the first gate wiring being interposed between the fourth source electrode and the second source electrode, a fourth drain electrode provided between the fourth source electrode and the first gate wiring, and a fourth gate electrode provided between the fourth source electrode and the fourth drain electrode in the first direction. This allows a plurality of transistors to be arranged in the first direction.
(5) In the above (4), the semiconductor device may further include a fifth transistor provided on the main surface, the fifth transistor including the first source electrode, a fifth drain electrode electrically connected to the fourth drain electrode, and a fifth gate electrode interposed between the first source electrode and the fifth drain electrode in the first direction and electrically connected to the first gate wiring. This allows a plurality of transistors to be arranged in the second direction.
(6) In the above (4) or (5), the back metal layer may be electrically connected to the fourth source electrode through a fourth via hole which overlaps the fourth source electrode when viewed in the thickness direction. This makes it possible to make the source inductances of the first to fourth transistors uniform, and to make the high-frequency characteristics of the semiconductor device more uniform.
(7) In the above (4) or (5), the semiconductor device may have no via hole for electrically connecting the fourth source electrode and the back surface metal layer, and a width of the fourth source electrode in the first direction is smaller than a width of the second source electrode in the first direction. This allows the semiconductor device to be downsized.
(8) In the above (7), the semiconductor device may further include a wiring crossing the first gate wiring in a non-contact manner and connecting the second source electrode and the fourth source electrode. This makes it possible to make the source inductances of the second transistor and the fourth transistor uniform, and to make the high-frequency characteristics of the semiconductor device more uniform.
(9) In any one of the above (1) to (8), the semiconductor device may further include a gate bus bar provided on the main surface and electrically connected to the second gate electrode and the first gate wiring, and a drain bus bar provided on the main surface electrically connected to the first drain electrode and the second drain electrode, the first transistor and the second transistor being interposed between the gate bus bar and the drain bus bar in the second direction. Thus, the gate potential can be supplied from the gate bus bar to the first and second gate electrodes, and the drain potential can be supplied from the drain bus bar to the first and second drain electrodes.
(10) A semiconductor device according to an embodiment of the present disclosure includes a substrate having a main surface and a back surface facing the main surface, a first gate wiring provided on the main surface, a first transistor provided on the main surface, the first transistor including a first drain electrode, a first gate electrode electrically connected to the first gate wiring, and a first source electrode, which are arranged in order in a first direction from the first gate wiring, a second transistor including a second drain electrode, a second gate electrode electrically connected to the first gate wiring, and a second source electrode, which are arranged in order from the first gate wiring in a direction opposite to the first direction, and which overlaps the first transistor when viewed from the first direction and is provided on the main surface. This makes it possible to suppress the gate-source parasitic capacitance, and hence to suppress the deterioration of the high-frequency characteristics.
(11) In the above (10), the semiconductor device may further include a third transistor provided on the main surface, the third transistor including a third drain electrode which is arranged in order in the first direction and overlaps the first drain electrode when viewed from a second direction intersecting the first direction, a third gate electrode electrically connected to the first gate wiring, and a third source electrode which overlaps the first source electrode when viewed from the first direction. This allows a plurality of transistors to be arranged in the second direction.
(12) In the above (11), the semiconductor device may further include a drain wiring connecting the first drain electrode and the third drain electrode, and a second gate wiring which crosses the drain wiring in a non-contact manner between the first drain electrode and the third drain electrode and electrically connects the third gate electrode and the first gate wiring. This allows a gate potential to be supplied to the third gate electrode.
(13) In the above (12), the semiconductor device may further include a first electrode provided between the first drain electrode and the third drain electrode on the main surface, provided between the second gate wiring and the first drain electrode or the third drain electrode, and supplied with a reference potential. This makes it possible to suppress the gate-drain parasitic capacitance, and thus to suppress the deterioration of the high-frequency characteristics.
(14) In the above (12) or (13), the semiconductor device may further include a second electrode provided on the main surface between the first gate wiring and the first drain electrode, and supplied with a reference potential. This makes it possible to suppress the gate-drain parasitic capacitance, and thus to suppress the deterioration of the high-frequency characteristics.
(15) In any one of the above (10) to (14), the semiconductor device may further include a back metal layer provided on the back surface and electrically connected to the first source electrode and the second source electrode through a first via hole and a second via hole which overlap the first source electrode and the second source electrode, respectively, when viewed in the thickness direction of the substrate. This makes it possible to suppress the source inductances of the first and second transistors.
(16) In any one of the above (10) to (15), the semiconductor device may further include a gate bus bar provided on the main surface and electrically connected to the first gate electrode, the second gate electrode, and the first gate wiring, and a drain bus bar provided on the main surface electrically connected to the first drain electrode and the second drain electrode, the first transistor and the second transistor being interposed between the gate bus bar and the drain bus bar in a second direction intersecting the first direction. Thus, the gate potential can be supplied from the gate bus bar to the first and second gate electrodes, and the drain potential can be supplied from the drain bus bar to the first and second drain electrodes.

A description will be given, with reference to the accompanying drawings, of embodiments of the semiconductor device according to the present disclosure. It is to be understood that the present disclosure is not limited to these embodiments, but is intended to be set forth by the appended claims and to include all modifications within the meaning and scope of the equivalents of the appended claims.

### First Embodiment

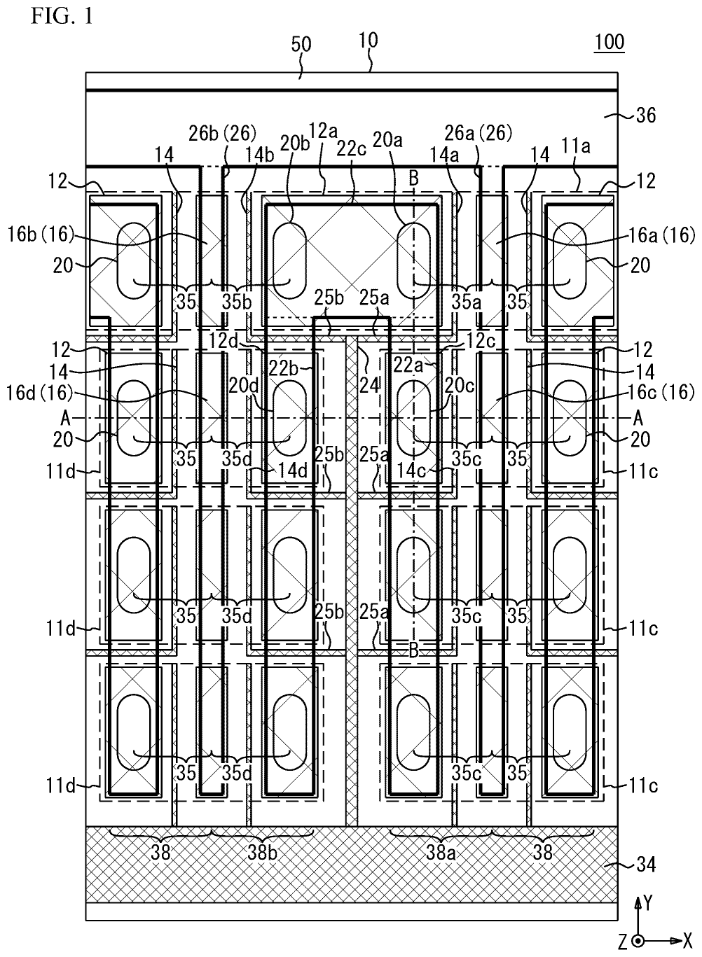

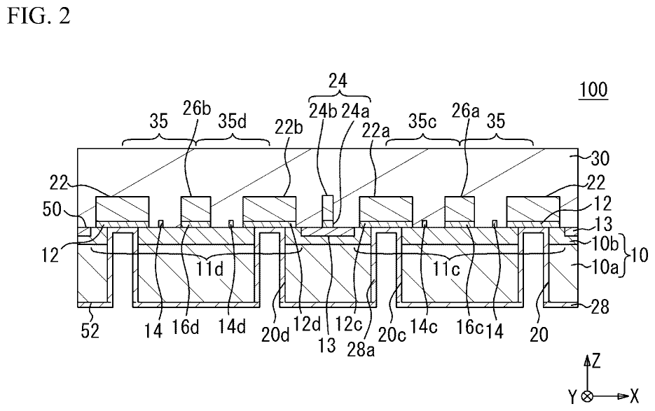

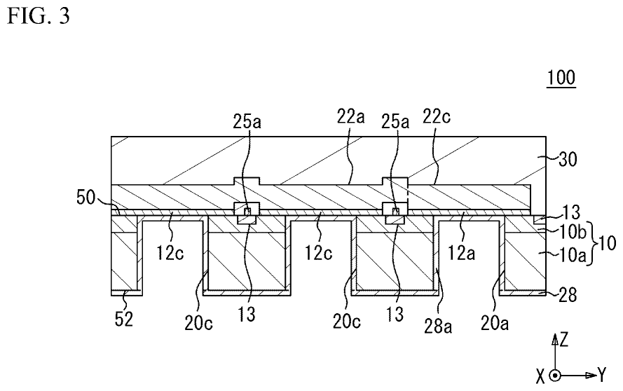

A semiconductor device used in an amplifier for amplifying a high frequency signal of, for example, 0.5 GHz to 10 GHz in a base station of mobile communication will be described as an example. FIG. 1 is a plan view of a semiconductor device according to a first embodiment. FIG. 2 is a cross-sectional view taken along a line A-A in FIG. 1. FIG. 3 is a cross-sectional view taken along a line B-B in FIG. 1. The thickness direction of a substrate 10 is defined as a Z direction, the extending direction of a finger-shaped source electrode 12, a gate electrode 14 and a drain electrode 16 is defined as a Y direction (a second direction intersecting with the first direction), and the arrangement direction of the source electrode 12, the gate electrode 14 and the drain electrode 16 is defined as an X direction (a first direction). In the plan views of FIGS. 1 and 2, it is difficult to see the source electrode 12 and the drain electrode 16 overlapping with a source wiring 22 and a drain wiring 26. Therefore, thick lines illustrating only the outer peripheries of the source wiring 22 and the drain wiring 26 are illustrated inside the source electrode 12 and the drain electrode 16 in a perspective view of the source wiring 22 and the drain wiring 26.

In each figure, the source electrodes 12, the gate electrodes 14, the source wirings 22, and transistors 35 (unit FETs) indicate general elements, and active regions 11a, 11c, 11d, source electrodes 12a, 12c, 12d, gate electrodes 14a, 14b, 14c and 14d, the drain electrodes 16a, 16b, 16c and 16d, the source wiring 22a, 22b and 22c, drain wiring 26a and 26b, and transistors 35a to 35d indicate specific elements included in the general elements. In the following, the transistors 35a to 35d will be mainly described by using the active regions 11a, 11c, 11d, the source electrodes 12a, 12c, 12d, the gate electrodes 14a to 14d, the drain electrodes 16a to 16d, the source wirings 22a to 22c, and the drain wirings 26a and 26b.

As illustrated in FIGS. 1 to 3, in the semiconductor device 100 of the first embodiment, the substrate 10 has a main surface 50 and a back surface 52 facing the main surface 50. The plurality of transistors 35 and 35a to 35d are provided on the main surface of the substrate 10. The transistors 35, 35a to 35d arranged in the Y direction form transistor groups 38, 38a and 38b. In the Y direction, a drain bus bar 36 and a gate bus bar 34 are provided on the main surface 50, and the transistor groups 38, 38a and 38b are interposed therebetween.

The transistors 35 closest to the drain bus bar 36 are transistors 35a and 35b. Transistors 35 closer to the gate bus bar 34 than transistors 35a and 35b are transistors 35c and 35d. The transistor group 38a includes one transistor 35a and three transistors 35c. The transistor group 38b includes one transistor 35b and three transistors 35d. The number of transistors 35c is one or more, and the number of transistors 35d is one or more.

The substrate 10 includes a substrate 10a and a semiconductor layer 10b provided on the substrate 10a. In the XY plane parallel to the X direction and the Y direction, a region of the semiconductor layer 10b inactivated by ion implantation or the like is an inactive region 13, and regions not inactivated are the active regions 11a, 11c and 11d. The active region 11a extends in the X direction. The active regions 11c and 11d are arranged in the X direction. Three active regions 11c are arranged in the Y direction, and three active regions 11d are arranged in the Y direction. The transistors 35a and 35b are provided in the active region 11a. The transistors 35c and 35d are provided in the active regions 11c and 11d, respectively.

The transistor 35a includes the source electrode 12a, the gate electrode 14a, and the drain electrode 16a. The gate electrode 14a is interposed between the source electrode 12a and the drain electrode 16a in the X direction. The source electrode 12a, the gate electrode 14a, and the drain electrode 16a are arranged in order in the + direction of the X direction.

The transistor 35b includes the source electrode 12a, the gate electrode 14b, and the drain electrode 16b. The source electrode 12a is interposed between the drain electrode 16b and the gate electrode 14a. The gate electrode 14b is interposed between the source electrode 12a and the drain electrode 16b in the X direction. The source electrode 12a, the gate electrode 14b and the drain electrode 16b are arranged in order in the − direction of the X direction. The transistors 35a and 35b share the source electrode 12a.

The transistor 35c includes the source electrode 12c, the gate electrode 14c, and the drain electrode 16c. The gate electrode 14c is interposed between the source electrode 12c and the drain electrode 16c in the X direction. The source electrode 12c is disposed in the source electrode 12a when viewed from the Y direction. That is, the source electrode 12c is not disposed outside the source electrode 12a when viewed from the Y direction. The plurality of source electrodes 12c are overlapped with each other when viewed from the Y direction. The plurality of drain electrodes 16c are overlapped with each other when viewed from the Y direction. The source electrode 12c, the gate electrode 14c, and the drain electrode 16c are arranged in order in the + direction of the X direction.

The transistor 35d includes the source electrode 12d, the gate electrode 14d, and the drain electrode 16d. The source electrode 12d is disposed in the source electrode 12a, with a gate wiring 24 interposed between the source electrode 12d and the source electrode 12c, as viewed in the Y direction. That is, the source electrode 12d is not disposed outside the source electrode 12a when viewed from the Y direction. The plurality of source electrodes 12d are overlapped with each other when viewed from the Y direction. The plurality of drain electrodes 16d are overlapped with each other when viewed from the Y direction. The gate electrode 14d is interposed between the source electrode 12d and the drain electrode 16d in the X direction. The source electrode 12d, the gate electrode 14d and the drain electrode 16d are arranged in order in the − direction of the X direction.

The source wiring 22c is provided on the source electrode 12a in contact with the source electrode 12a. The source wiring 22a (first source wiring) is provided in contact with the source electrode 12c. The source wiring 22a extends in the Y direction, electrically connects the plurality of source electrodes 12c to each other, and electrically connects the plurality of source electrodes 12c and the source wiring 22c. The source wiring 22b (second source wiring) is provided in contact with the source electrode 12d. The source wiring 22b extends in the Y direction, electrically connects the plurality of source electrodes 12d to each other, and electrically connects the plurality of source electrodes 12d and the source wiring 22c.

The drain wiring 26a is provided in contact with the drain electrodes 16a and 16c. The drain wiring 26a extends in the Y direction, electrically connects the plurality of drain electrodes 16a and 16c to each other, and electrically connects the plurality of drain electrodes 16a and 16c to the drain bus bar 36. The drain wiring 26b is provided in contact with the drain electrodes 16b and 16d. The drain wiring 26b extends in the Y direction, electrically connects the plurality of drain electrodes 16b and 16d to each other, and electrically connects the plurality of drain electrodes 16b and 16d to the drain bus bar 36.

The gate wiring 24 (first gate wiring) extending in the Y direction is provided on the inactive region 13 between the transistors 35c and 35d. The gate wiring 24 is disposed in the source electrode 12a as viewed from the Y direction. The gate wiring 24 is electrically connected to the gate bus bar 34. The gate wiring 24 includes a gate metal layer 24a provided on the substrate 10 and a wiring layer 24b provided on the gate metal layer 24a in contact with the gate metal layer 24a.

A gate wiring 25a (second gate wiring) extending in the X direction is provided between the transistors 35a and 35c and on the inactive region 13 between the transistors 35c. The gate wiring 25a crosses the source wiring 22a in a non-contact manner, and electrically connects the gate wiring 24 to the gate electrodes 14a and 14c. A gate wiring 25b (third gate wiring) extending in the X direction is provided between the transistors 35b and 35d and on the inactive region 13 between the transistors 35d. The gate wiring 25b intersects the source wiring 22b in a non-contact manner, and electrically connects the gate wiring 24 to the gate electrodes 14b and 14d. As a result, the gate electrodes 14a to 14d are electrically connected to the gate bus bar 34 via the gate wirings 24, 25a and 25b. The gate electrodes 14c and 14d of the transistors 35c and 35d closest to the gate bus bar 34 are electrically connected directly to the gate bus bar 34 without passing through the gate wirings 24, 25a and 25b.

The via holes 20, 20a to 20d extend through the substrate 10. The via holes 20a and 20b overlap the source electrode 12a when viewed in the Z direction, and are electrically connected to the source electrode 12a. The number of the via holes 20a or 20b that overlap with one source electrode 12a and are electrically connected to the source electrode 12a may be one. The via holes 20c and 20d are overlapped with the source electrodes 12c and 12d, respectively, as viewed in the Z direction, and electrically connected to the source electrodes 12c and 12d, respectively. A metal layer 28 is provided on the back surface 52 of the substrate 10. A metal layer 28a is provided on the inner surfaces of the via holes 20 and 20a to 20d. As a result, the metal layer 28 is electrically connected to the source electrode 12a through the via holes 20a and 20b, and is electrically connected to the source electrodes 12c and 12d through the via holes 20c and 20d, respectively. The planar shape of the via holes 20a to 20d may be oval, ellipse, rounded square, or circular.

A source potential (for example, a reference potential such as a ground potential) is supplied from the metal layer 28 to the source electrodes 12a, 12c and 12d through the metal layer 28a in the via holes 20a to 20d, respectively. A gate potential (for example, a high-frequency signal and a gate bias voltage) is supplied from the gate bus bar 34 to the gate electrodes 14a to 14d via the gate wirings 24, 25a and 25b. The drain bias voltage is supplied from the drain bus bar 36 to the drain electrodes 16a to 16d through the drain wirings 26a and 26b. The high frequency signals amplified by the transistors 35a to 35d are output from the drain wirings 26a and 26b to the drain bus bar 36.

The + end of the gate electrode 14c in the Y direction and the − end of the gate electrode 14a in the Y direction may be connected, and the + end of the gate electrode 14d in the Y direction and the − end of the gate electrode 14b in the Y direction may be connected. However, when the gate electrodes 14c and 14a are directly connected and the gate electrodes 14d and 14b are directly connected, the high-frequency signal is input from the − end of the gate electrodes 14c and 14d in the Y direction in the transistors 35c and 35d. When the high frequency signals are input to the gate electrodes 14c and 14d from both ends of the + and − ends in the Y direction of the gate electrodes 14c and 14d, the high frequency characteristics of the transistors 35c and 35d are deteriorated due to the phase difference or the like. In the first embodiment, the + end of the gate electrode 14c in the Y direction and the − end of the gate electrode 14a in the Y direction are not connected, and the + end of the gate electrode 14d in the Y direction and the − end of the gate electrode 14b in the Y direction are not connected. This makes it possible to suppress deterioration of the high-frequency characteristics of the transistors 35c and 35d.

When the semiconductor device 100 is, for example, a nitride semiconductor device, the substrate 10a is, for example, a silicon carbide (SiC) substrate, a silicon (Si) substrate, a gallium nitride (GaN) substrate, or a sapphire (Al2O3) substrate. The semiconductor layer 10b includes a nitride semiconductor layer such as a gallium nitride layer, an aluminum gallium nitride (AlGaN) layer, and/or an indium gallium nitride (InGaN) layer. When the transistors 35a to 35d are GaN HEMT (Gallium Nitride High Electron Mobility Transistors), the semiconductor layer 10b includes a gallium nitride channel layer provided on the substrate 10a and an aluminum gallium nitride barrier layer provided on the channel layer. When the semiconductor device 100 is, for example, a gallium arsenide (GaAs)-based semiconductor device, the substrate 10a is, for example, a gallium arsenide substrate. The semiconductor layer 10b includes an arsenide semiconductor layer, such as, for example, a gallium arsenide layer, an aluminum gallium arsenide (AlGaAs) layer and/or an indium gallium arsenide (InGaAs) layer. The semiconductor device 100 may be a silicon semiconductor device such as LDMOS (Laterally Diffused Metal Oxide Semiconductor).

The source electrodes 12a, 12c and 12d and the drain electrodes 16a to 16d are metal films, for example, a titanium film and an aluminum film are formed on the substrate 10. The gate electrodes 14a to 14d and the gate metal layer 24a are metal films, and for example, a nickel film and a gold film are formed on the substrate 10. The source wirings 22a to 22c, the drain wirings 26a and 26b, the wiring layer 24b, the metal layers 28 and 28a, and the drain bus bar 36 are, for example, gold layers, copper layers, or aluminum layers. An insulating layer 30 is an organic insulating layer such as a polyimide layer or a BCB (Benzocyclobutane) layer.

The width of the source electrode 12a in the X direction is, for example, 50 μm to 150 μm. The widths of the source electrodes 12c and 12d in the X direction are, for example, 5 μm to 80 μm. The gate length of the gate electrodes 14a to 14d in the X direction is, for example, 0.10 μm to 2 μm. The width of the drain electrodes 16a to 16d in the X direction is, for example, 5 μm to 150 μm. The width of the gate wiring 24 in the X direction is, for example, 5 μm to 100 μm. The widths of the gate wirings 25a and 25b in the Y direction are, for example, 3 μm to 20 μm. The gate widths of the transistors 35a to 35d in the Y direction are, for example, 50 μm to 500 μm. The width of the via holes 20a to 20d in the X direction is, for example, 10 μm to 60 μm.

The widths of the source wirings 22a to 22c and the drain wirings 26a and 26b in the X direction are the same as, slightly smaller than, or slightly larger than the widths of the source electrodes 12a, 12c, and 12d and the drain electrodes 16a and 16d in the X direction, respectively. The thicknesses of the source wirings 22a to 22c and the drain wirings 26a and 26c are, for example, 1 μm to 20 μm.

### FIRST COMPARATIVE EXAMPLE

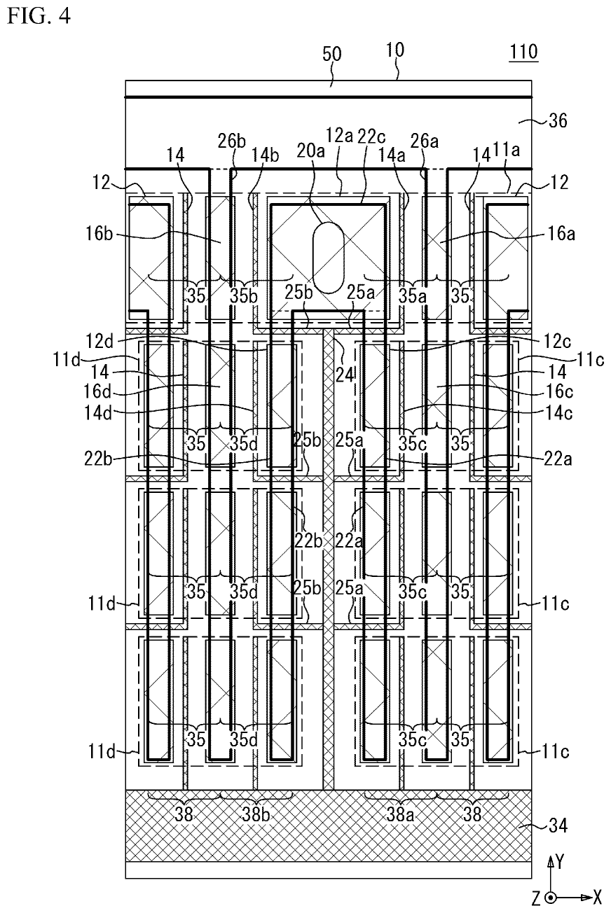

FIG. 4 is a plan view of a semiconductor device according to a first comparative example. As illustrated in FIG. 4, a semiconductor device 110 of the first comparative example is not provided with the via holes 20c and 20d. The other configuration is the same as that of the first embodiment.

In the first comparative example, since the gate potential is supplied to the gate electrodes 14a to 14d through the gate wirings 24, 25a and 25b, the gate resistance can be reduced. Since the gate wiring 24 does not overlap the source electrodes 12c and 12d in plan view, the gate-source parasitic capacitance can be reduced as compared with the case of the first and second patent documents. However, the source potential is supplied to the source electrodes 12c and 12d via the source wirings 22a and 22b, respectively. This increases the source inductance of the transistors 35c and 35d. In particular, the source inductances of the transistors 35c and 35d closest to the gate bus bar 34 become the largest. This causes non-uniformity in transistor characteristics between the transistors 35a and 35c and between the transistors 35b and 35d. This deteriorates the high-frequency characteristics of the transistor groups 38a and 38b.

By connecting the via holes 20c and 20d to the source electrodes 12c and 12d, respectively, as in the first embodiment, the reference potentials are supplied from the metal layer 28 to the source electrodes 12c and 12d through the via holes 20c and 20d. This makes it possible to make the source inductance uniform between the transistors 35a and 35c and between the transistors 35b and 35d, and to make the transistor characteristics uniform. Therefore, deterioration of the high-frequency characteristics of the transistor groups 38a and 38b can be suppressed.

### Second Embodiment

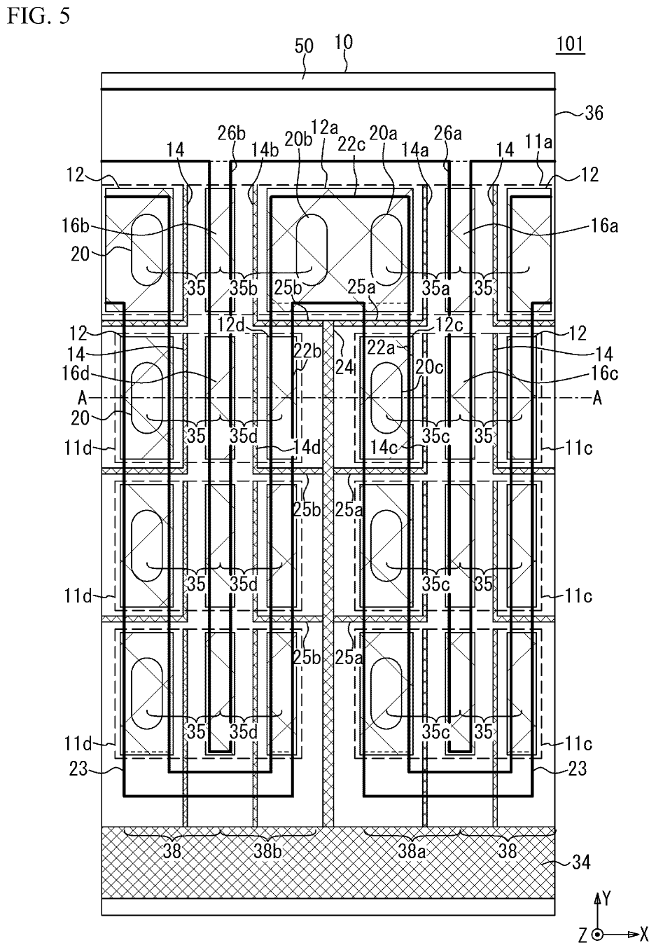

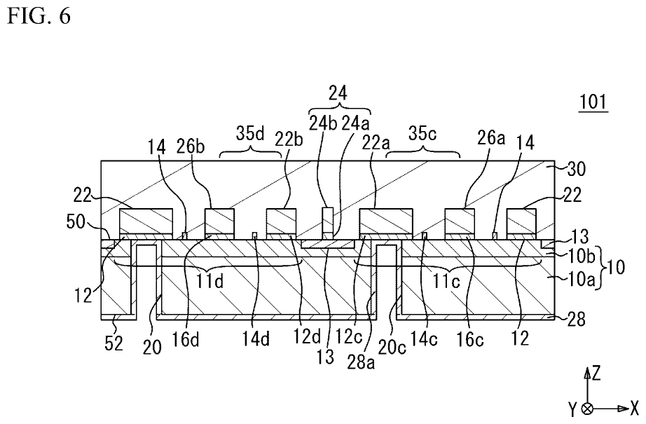

FIG. 5 is a plan view of a semiconductor device according to a second embodiment. FIG. 6 is a cross-sectional view taken along the line A-A in FIG. 5. As illustrated in FIGS. 5 and 6, in a semiconductor device 101 of the second embodiment, the via hole 20d is not connected to the source electrode 12d. The width of the source electrode 12d in the X direction is smaller than the width of the source electrode 12c in the X direction. The wiring 23 electrically connects the source wirings 22 and 22a between which the drain wiring 26a is interposed, and electrically connects the source wirings 22 and 22b between which the drain wiring 26b is interposed. The wiring 23 is provided on the inactive region 13 between the transistor groups 38, 38a and 38b and the gate bus bar 34, and intersects the gate electrodes 14, 14a and 14b in a non-contact manner. The other configurations are the same as those of the first embodiment, and the description thereof is omitted.

In the transistor group 38a, since the via hole 20c is connected to the source electrode 12c, deterioration of the high-frequency characteristics can be suppressed. In the transistor group 38b, since the via hole 20d is not connected to the source electrode 12d, the degradation of the high-frequency characteristic cannot be suppressed, but the degradation of the high-frequency characteristic can be suppressed as a whole. Furthermore, since the width of the source electrode 12d in the X direction can be reduced, the chip size can be reduced as compared with the first embodiment.

### First Modification of Second Embodiment

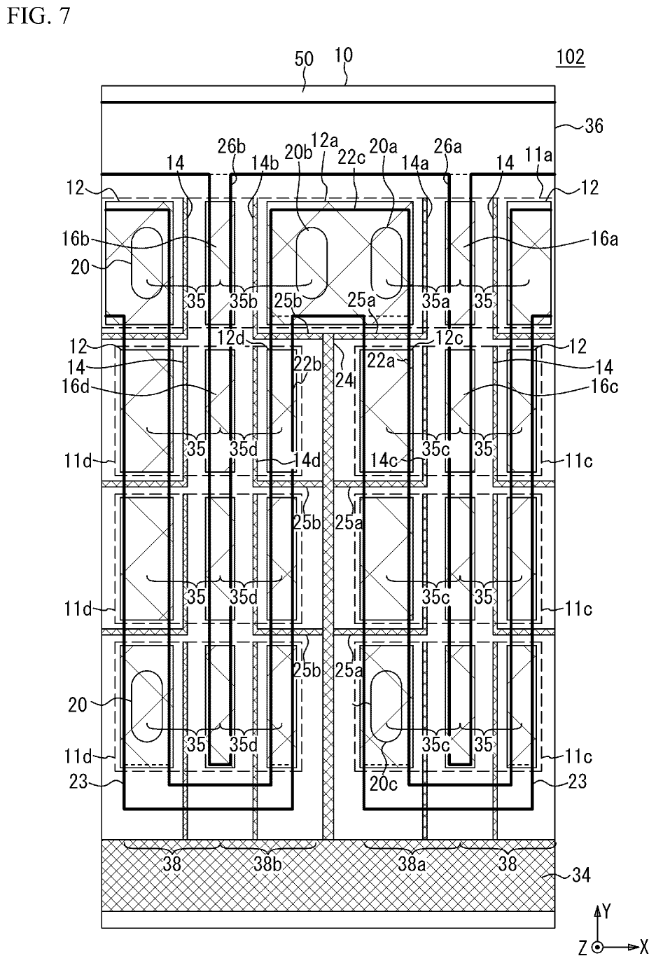

FIG. 7 is a plan view of a semiconductor device according to a first modification of the second embodiment. As illustrated in FIG. 7, in a semiconductor device 102 of the first modification of the second embodiment, the via hole 20c is not connected to the source electrode 12c except for the source electrode 12c closest to the gate bus bar 34. The other configurations are the same as those of the second embodiment, and the description thereof is omitted.

In the first comparative example, the transistor 35c closest to the gate bus bar 34 has the largest source inductance. Therefore, the via hole 20c may be connected only to the source electrode 12c closest to the gate bus bar 34 among the source electrodes 12c. In the first embodiment, the via hole 20c may be connected only to the source electrode 12c closest to the gate bus bar 34 among the source electrodes 12c. The via hole 20d may be connected only to the source electrode 12d closest to the gate bus bar 34 among the source electrodes 12d. The source electrode 12c connected to the via hole 20 is not the source electrode 12c closest to the gate bus bar 34, and the via hole 20c need not be connected to the source electrode 12c closest to the gate bus bar 34.

### Second Modification of Second Embodiment

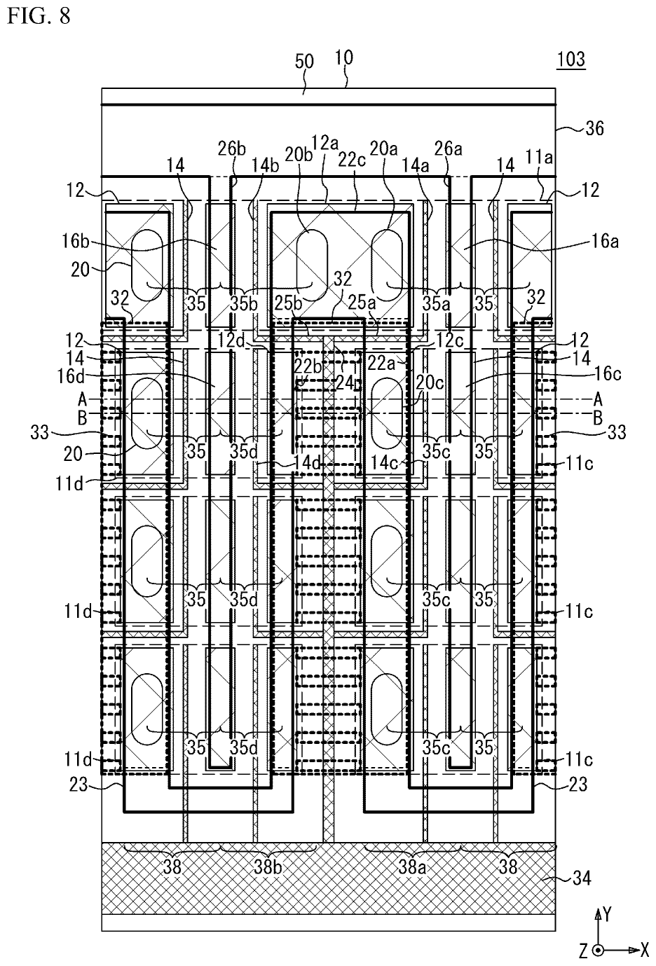

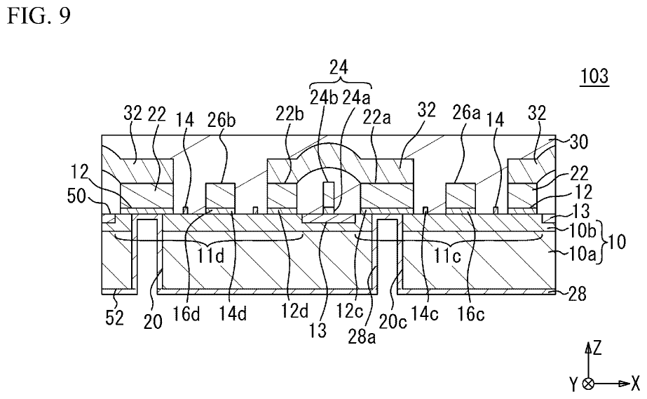

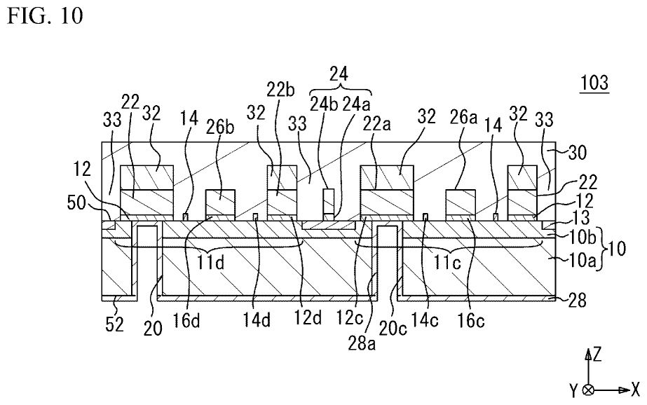

FIG. 8 is a plan view of a semiconductor device according to a second modification of the second embodiment. FIG. 9 is a cross-sectional view taken along the line A-A in FIG. 8. FIG. 10 is a cross-sectional view taken along the line B-B in FIG. 8. As illustrated in FIGS. 8 to 10, in the semiconductor device 103 of the second modification of the second embodiment, a wiring 32 is provided on the source wirings 22a and 22b in contact with each other. The wiring 32 crosses over the gate wiring 24 in a non-contact manner through the insulating layer 30, and electrically connects the source wirings 22a and 22b. The wiring 32 has a plurality of openings 33 above the gate wiring 24. The plurality of openings 33 are arranged in the Y direction. The openings 33 are for removing photoresist or the like under the wiring 32 when the wiring 32 is formed. The openings 33 may not be provided. The wiring 32 also has a function of suppressing a gate-drain parasitic capacitance generated between the gate wiring 24 and the drain wirings 26a and 26b.

The source electrode 12d is supplied with a source potential from the source wiring 22a through the wiring 32 in addition to the source wiring 22b. This can reduce the source inductance of the transistor 35d. Therefore, deterioration of the high-frequency characteristics of the transistor group 38b can be suppressed.

According to the first and second embodiments and the modification thereof, the transistor 35a is a first transistor, and the source electrode 12a, the gate electrode 14a, and the drain electrode 16a are a first source electrode, a first gate electrode, and a first drain electrode, respectively. One of the transistors 35c is a second transistor, and the source electrode 12c, the gate electrode 14c, and the drain electrode 16c are a second source electrode, a second gate electrode, and a second drain electrode, respectively. The metal layer 28 (back metal layer) is electrically connected to the source electrode 12a and the source electrode 12c through a via hole 20a (first via hole) and a via hole 20c (second via hole), respectively. This makes it possible to equalize the source inductances of the transistors 35a and 35c. Therefore, the high-frequency characteristics of the transistors 35a and 35c can be made uniform, and thus the high-frequency characteristics of the semiconductor device can be made uniform.

Another one of the transistors 35c is a third transistor, and the source electrode 12c, the gate electrode 14c, and the drain electrode 16c are a third source electrode, a third gate electrode, and a third drain electrode, respectively. This allows three or more transistors to be arranged in the Y direction.

The metal layer 28 is electrically connected to the third source electrode through another via hole 20c (third via hole). This makes it possible to equalize the source inductances of the plurality of transistors 35c. Therefore, the high frequency characteristics of the plurality of transistors 35c can be made uniform, and therefore the high frequency characteristics of the semiconductor device can be made uniform.

One of the transistors 35d is a fourth transistor, and the source electrode 12d, the gate electrode 14d, and the drain electrode 16d are a fourth source electrode, a fourth gate electrode, and a fourth drain electrode, respectively. This allows the plurality of transistors 35 to be arranged in the X direction.

The transistor 35b is a fifth transistor, and the source electrode 12a, the gate electrode 14b, and the drain electrode 16b are a first source electrode, a fifth gate electrode, and a fifth drain electrode, respectively. Thus, the plurality of transistors 35 can be arranged in the Y direction.

As in the first embodiment, the metal layer 28 is electrically connected to the source electrode 12d through the via hole 20d (fourth via hole). This makes it possible to equalize the source inductances of the transistors 35b and 35d. Therefore, the high-frequency characteristics of the transistors 35b and 35d can be made uniform, and thus the high-frequency characteristics of the semiconductor device can be made uniform.

According to the second embodiment and its modification, no via hole is provided for electrically connecting the source electrode 12d and the metal layer 28. The width of the source electrode 12d in the X direction is smaller than the width of the source electrode 12c in the X direction. This allows the semiconductor device to be downsized. From the viewpoint of miniaturization, the width of the source electrode 12d in the X direction is, for example, 0.9 times or less, 0.7 times or less, 0.5 times or less of the width of the source electrode 12c in the X direction. The width of the source electrode 12d in the X direction is, for example, 0.1 times or more the width of the source electrode 12c in the X direction.

According to the second modification of the second embodiment, the wiring 32 crosses the gate wiring 24 in a non-contact manner, and electrically connects the source electrode 12c and the source electrode 12d. This makes it possible to equalize the source inductances of the transistors 35b and 35d. Therefore, the high-frequency characteristics of the transistors 35b and 35d can be made uniform, and thus the high-frequency characteristics of the semiconductor device can be made uniform.

The first and second embodiments and the modifications thereof include the gate bus bar 34 to which the gate wiring 24 is electrically connected, and the drain bus bar 36 to which the drain wirings 26a and 26b are electrically connected. As a result, the gate potential can be supplied from the gate bus bar 34 to the gate electrodes 14a to 14d, and the drain potential can be supplied from the drain bus bar 36 to the drain electrodes 16a to 16d.

Although the first and second embodiments and the modifications thereof have been described as the embodiments in which four transistor groups 38, 38a and 38b are arranged in the X direction, five or more transistor groups 38, 38a and 38b may be arranged in the X direction. The transistors 35c and 35d may be arranged in the Y direction one or more than one.

In the first and second embodiments and the modifications thereof, the plurality of drain electrodes 16 (for example, drain electrodes 16a and 16c) electrically connected to the same drain wiring 26 (for example, drain wiring 26a) are separated from each other in the inactive region 13. The plurality of drain electrodes 16 (for example, drain electrodes 16a and 16c) to which the drain wiring 26 (for example, drain wiring 26a) is electrically connected may be connected to each other in the inactive region 13. In the transistor 35 (for example, the transistor 35a), the source electrode 12 and the source wiring 22 (for example, the source electrode 12a and the source wiring 22c) can be collectively referred to as a source electrode, and the drain electrode 16 and the drain wiring 26 (for example, the drain electrode 16a and the drain wiring 26a) can be collectively referred to as a drain electrode.

### Third Embodiment

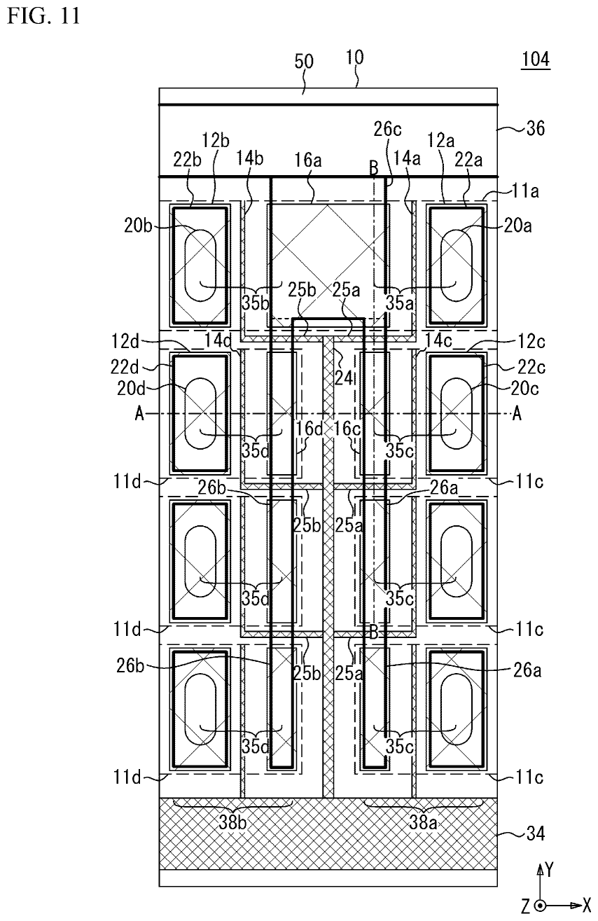

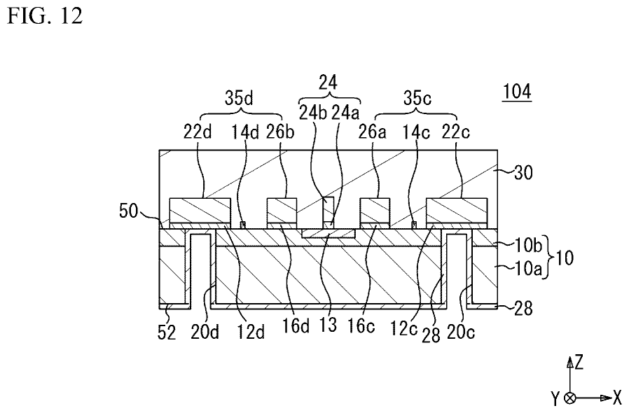

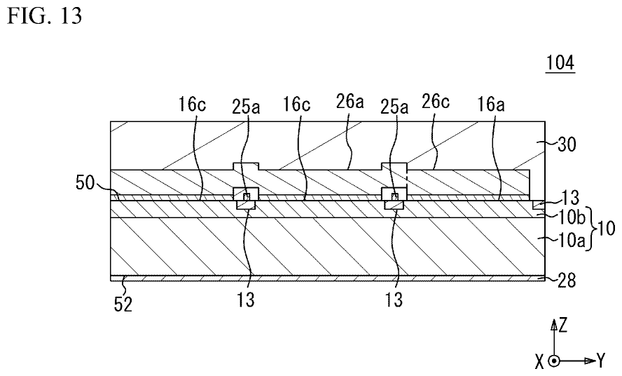

FIG. 11 is a plan view of a semiconductor device according to a third embodiment. FIG. 12 is a cross-sectional view taken along the line A-A in FIG. 11. FIG. 13 is a cross-sectional view taken along the line B-B in FIG. 11.

As illustrated in FIGS. 11 to 13, in a semiconductor device 104 of the third embodiment, in the transistor 35a, the drain electrode 16a, the gate electrode 14a, and the source electrode 12a are arranged in order in the + direction of the X direction. In the transistor 35b, the drain electrode 16a, the gate electrode 14b, and the source electrode 12b are arranged in order in the − direction of the X direction. The transistors 35a and 35b share the drain electrode 16a.

In the transistor 35c, the drain electrode 16c, the gate electrode 14c, and the source electrode 12c are arranged in order from the gate wiring 24 in the + direction of the X direction. In the transistor 35d, the drain electrode 16d, the gate electrode 14d, and the source electrode 12d are arranged in order from the gate wiring 24 in the − direction of the X direction.

Source wirings 22a to 22d are provided on the source electrodes 12a to 12d in contact with each other. A drain wiring 26c is provided on the drain electrode 16a in contact with the drain electrode 16a. The drain wiring 26a (first drain wiring) is provided on the drain electrode 16c in contact therewith. The drain wiring 26a extends in the Y direction, electrically connects the plurality of drain electrodes 16c to each other, and electrically connects the plurality of drain electrodes 16c and the drain wiring 26c. The drain wiring 26b (second drain wiring) is provided on the drain electrode 16d in contact therewith. The drain wiring 26b extends in the Y direction, electrically connects the plurality of drain electrodes 16d to each other, and electrically connects the plurality of drain electrodes 16d and the drain wiring 26c.

The gate wiring 25a crosses the drain wiring 26a in a non-contact manner, and electrically connects the gate wiring 24 to the gate electrodes 14a and 14c. The gate wiring 25b crosses the drain wiring 26b in a non-contact manner, and electrically connects the gate wiring 24 to the gate electrodes 14b and 14d.

The via holes 20a to 20d connect to the source electrodes 12a to 12d. The metal layer 28 is electrically connected to the source electrodes 12a to 12d through the via holes 20a to 20d, respectively. The other configurations are the same as those of the first embodiment, and the description thereof is omitted.

### FIRST COMPARATIVE EXAMPLE

In the comparative example 1 illustrated in FIG. 4, the gate wiring 24 is provided between the source electrode 12c and the source wiring 22a, and between the source electrode 12d and the source wiring 22b. This increases the gate-source parasitic capacitance and deteriorates the high-frequency characteristics.

In the third embodiment, the gate wiring 24 is provided between the drain electrode 16c and the drain wiring 26a, and the drain electrode 16d and the drain wiring 26b. This can suppress an increase in the gate-source parasitic capacitance. In the third embodiment, the gate-drain parasitic capacitance is increased as compared with the first comparative example. By suppressing the gate-source capacitance, the frequency at which the maximum stable gain switches to the maximum available power gain can be increased. By suppressing the gate-drain capacitance, the maximum stable gain at the same frequency can be improved. The third embodiment is particularly effective in increasing the frequency at which the maximum stable gain is switched to the maximum available power gain.

### First Modification of Third Embodiment

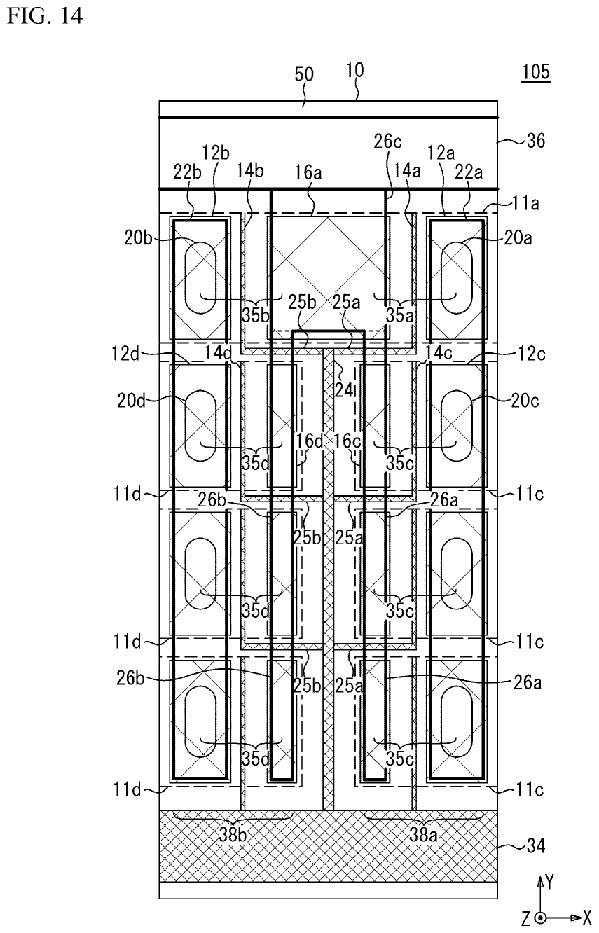

FIG. 14 is a plan view of a semiconductor device according to a first modification of the third embodiment. As illustrated in FIG. 14, in a semiconductor device 105 of the first modification of the third embodiment, a source wiring 22a is provided in contact with the source electrode 12a and the plurality of source electrodes 12c. A source wiring 22b is provided in contact with the source electrode 12b and the plurality of source electrodes 12d. The other configurations are the same as those of the third embodiment, and the description thereof is omitted.

As in the first modification of the third embodiment, the source wiring 22a may be provided commonly to the source electrode 12a and the plurality of source electrodes 12c, and the source wiring 22b may be provided commonly to the source electrode 12b and the plurality of source electrodes 12d. In this case, the via holes 20a and 20c need not be connected to some of the source electrodes 12a and the plurality of source electrodes 12c. The via holes 20b and 20d may not be connected to some of the source electrodes 12b and the plurality of source electrodes 12d. By providing the source wirings 22a to 22d for the source electrodes 12a to 12d, respectively, as in the third embodiment, the gate-source parasitic capacitance can be reduced.

### Second Modification of Third Embodiment

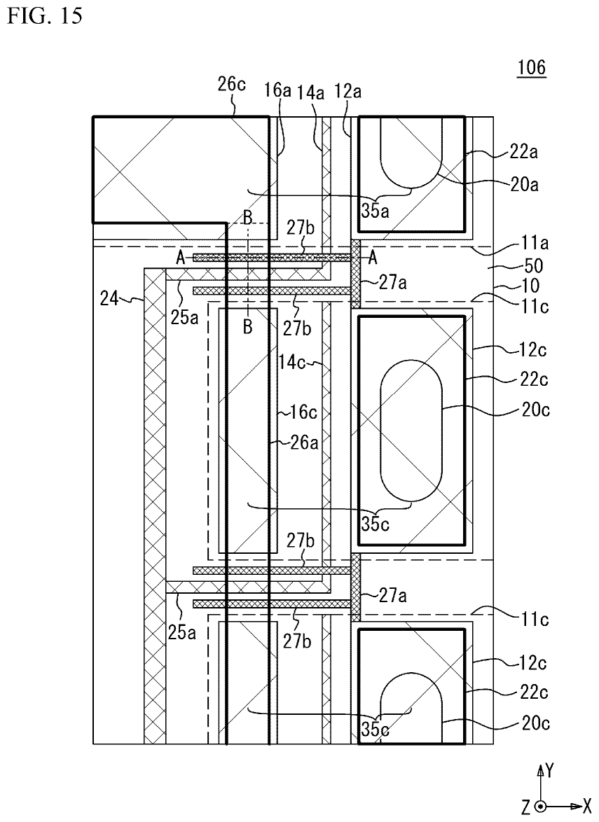

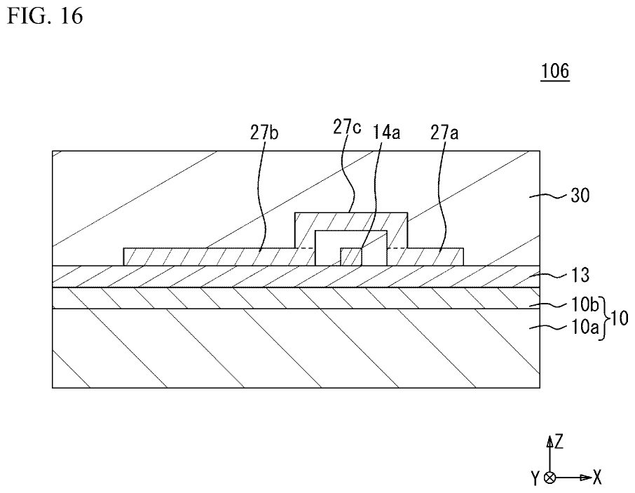

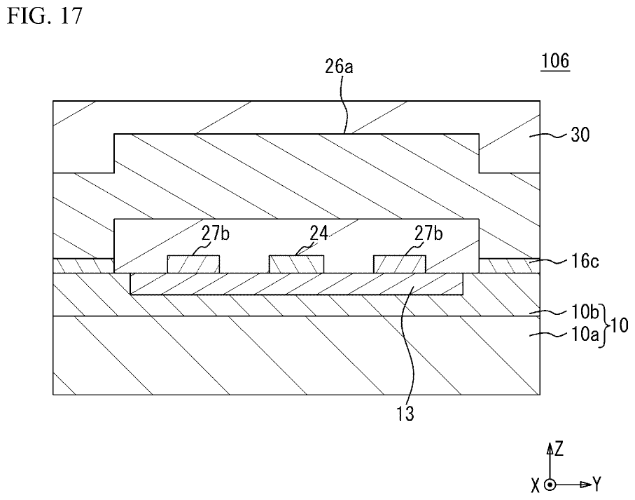

FIG. 15 is an enlarged plan view of a semiconductor device according to a second modification of the third embodiment. FIG. 16 is a cross-sectional view taken along the line A-A in FIG. 15. FIG. 17 is a cross-sectional view taken along the line B-B in FIG. 15.

As illustrated in FIGS. 15 to 17, in a semiconductor device 106 of the second modification of the third embodiment, an electrode 27a for electrically connecting the source electrodes 12c is provided between the source electrodes 12a and 12c. Electrodes 27b are provided on both sides of the gate wiring 25a in the Y direction between the drain electrodes 16a and 16c and between the drain electrodes 16c. A wiring 27c crosses the gate electrode 14a in a non-contact manner, and electrically connects the electrodes 27a and 27b. The electrode 27b is electrically connected to the source electrodes 12a and 12c via the electrode 27a and is short-circuited. Therefore, the reference potential supplied to the source electrodes 12a and 12c is supplied to the electrode 27b.

The electrode 27b can shield the electric field between the gate wiring 25a and the drain electrodes 16a and 16c and the drain wiring 26a. Therefore, the gate-drain parasitic capacitance can be reduced, and deterioration of the high-frequency characteristics can be suppressed. The other configurations are the same as those of the third embodiment, and the description thereof is omitted.

### Third Modification of Third Embodiment

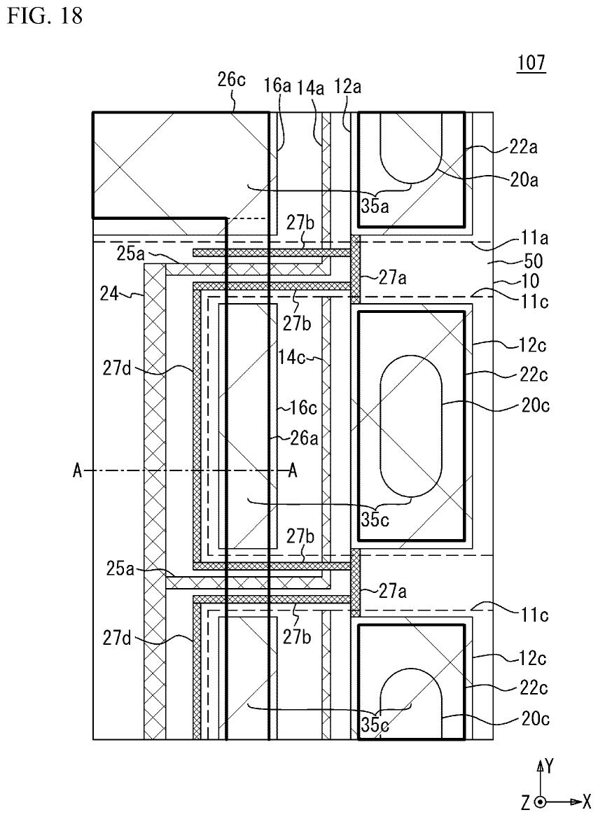

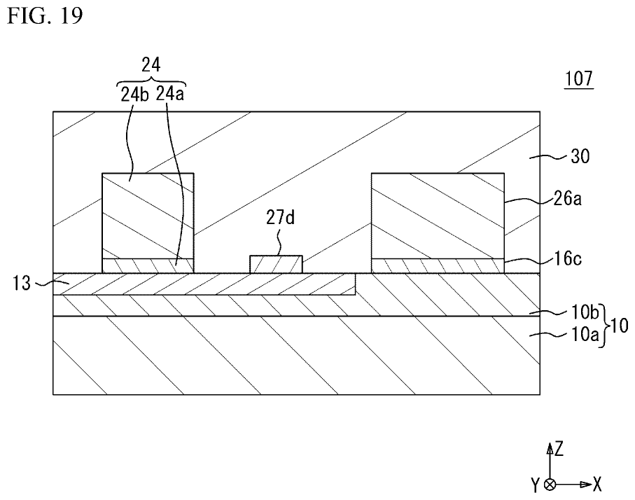

FIG. 18 is a plan view of a semiconductor device according to a third modification of the third embodiment, and is an enlarged plan view of the transistors 35a and 35c. FIG. 19 is a cross-sectional view taken along the line A-A in FIG. 18.

As illustrated in FIGS. 18 and 19, in a semiconductor device 107 of the third modification of the third embodiment, an electrode 27d is provided between the drain electrode 16c and the drain wiring 26a and the gate wiring 24. The electrode 27d is electrically connected to the electrode 27b . As a result, the reference potential supplied to the source electrodes 12a and 12c is supplied to the electrode 27d.

The electrode 27d can shield the electric field between the gate wiring 24, and the drain electrodes 16a and the drain wiring 26a. Therefore, the gate-drain parasitic capacitance can be reduced, and deterioration of the high-frequency characteristics can be suppressed. The other configuration is the same as that of the second modification of the third embodiment, and the description thereof is omitted.

According to the third embodiment and its modifications, the transistor 35c is a first transistor, and the drain electrode 16c (first drain electrode), the gate electrode 14c (first gate electrode), and the source electrode 12c (first source electrode) are arranged in order in the + direction of the X direction from the gate wiring 24. The transistor 35d is a second transistor, and overlaps the transistor 35c when viewed from the X direction. In the transistor 35d, the drain electrode 16d (second drain electrode), the gate electrode 14d (second gate electrode), and the source electrode 12d (second source electrode) are arranged in order in the − direction of the X direction (direction opposite to the first direction) from the gate wiring 24. This increases the distance between the source electrode 12c and the gate wiring 24 and between the source wiring 22a and the gate wiring 24 and increases the distance between the source electrode 12d and the gate wiring 24 and between the source wiring 22b and the gate wiring 24. Therefore, since the gate-source parasitic capacitance can be suppressed, the deterioration of the high-frequency characteristics can be suppressed.

The transistor 35a is a third transistor, and a drain electrode 16a (third drain electrode), a gate electrode 14a (third gate electrode), and a source electrode 12a (third source electrode) are arranged in order in the + direction of the X direction. The drain electrode 16a and the source electrode 12a overlap with the drain electrode 16c and the source electrode 12c, respectively, when viewed in the Y direction. This allows a plurality of transistors 35a and 35c to be arranged in the Y direction.

The drain wiring 26a electrically connects the drain electrodes 16a and 16c. The gate wiring 25a (second gate wiring) crosses the drain wiring 26a between the drain electrodes 16a and 16c in a non-contact manner, and electrically connects the gate electrode 14a and the gate wiring 24. This allows a gate potential to be supplied to the gate electrode 14a.

The metal layer 28 (back metal layer) is electrically connected to the source electrode 12c and the source electrode 12d through the via hole 20c (first via hole) and the via hole 20d (second via hole), respectively. This makes it possible to suppress the source inductances of the transistors 35c and 35d.

The semiconductor device includes the gate bus bar 34 to which the gate wiring 24 is electrically connected, and the drain bus bar 36 to which the drain wirings 26a and 26b are electrically connected. This allows the gate potential to be supplied from the gate bus bar 34 to the gate electrodes 14a to 14d, and the drain potential to be supplied from the drain bus bar 36 to the drain electrodes 16a, 16c and 16d.

As in the second and third modifications of the third embodiment, the electrode 27b (first electrode) is provided between the drain electrodes 16a and 16c in the Y direction and between the gate wiring 25a and the drain electrodes 16a and 16c, and a reference potential is supplied thereto. This makes it possible to suppress the gate-drain parasitic capacitance, and thus to suppress the deterioration of the high-frequency characteristics. The electrode 27b may be provided between the gate wiring 25a and the drain electrode 16a or 16c.

As in the third modification of the third embodiment, the electrode 27d (second electrode) is provided between the gate wiring 24 and the drain electrode 16c, and a reference potential is supplied thereto. This makes it possible to suppress the gate-drain parasitic capacitance, and thus to suppress the deterioration of the high-frequency characteristics.

Although the third embodiment and the modification thereof have described the example in which two transistor groups 38a and 38b are arranged in the X direction, three or more transistor groups 38a and 38b may be arranged in the X direction. The transistors 35c and 35d may be arranged in the Y direction one or more than one.

In the third embodiment and the modifications thereof, the plurality of source electrodes 12 (for example, source electrodes 12a and 12c) electrically connected to the same source wiring 22 (for example, source wiring 22a) are separated from each other in the inactive region 13. The plurality of source electrodes 12 (for example, source electrodes 12a and 12c) to which the source wiring 22 (for example, source wiring 22a) is electrically connected may be connected to each other in the inactive region 13. In the transistor 35 (for example, the transistor 35a), the source electrode 12 and the source wiring 22 (for example, the source electrode 12a and the source wiring 22a) can be collectively referred to as a source electrode, and the drain electrode 16 and the drain wiring 26 (for example, the drain electrode 16a and the drain wiring 26c) can be collectively referred to as a drain electrode.

The embodiments disclosed herein are to be considered as illustrative in all respects and not restrictive. The scope of the present disclosure is not in the sense set forth above, but is indicated by the claims, and is intended to include all modifications within the meaning and scope of the claims and equivalents.

What is claimed is:

1. A semiconductor device comprising:
a substrate having a main surface and a back surface facing the main surface;
a first transistor provided on the main surface, the first transistor including a first source electrode, a first drain electrode, and a first gate electrode interposed between the first source electrode and the first drain electrode in a first direction;
a second transistor provided on the main surface, the second transistor including a second source electrode interposed in the first source electrode as viewed from a second direction intersecting the first direction, a second drain electrode electrically connected to the first drain electrode, and a second gate electrode interposed between the second source electrode and the second drain electrode in the first direction;
a first gate wiring provided on the main surface disposed in the first source electrode when viewed from the second direction, and electrically connected to the first gate electrode, the second source electrode being interposed between the second gate electrode and the first gate wiring; and
a back metal layer provided on the back surface and electrically connected to the first source electrode and the second source electrode through a first via hole and a second via hole which overlap the first source electrode and the second source electrode, respectively, when viewed in the thickness direction of the substrate.

2. The conductor device according to claim 1, further comprising a third transistor provided on the main surface, the third transistor including:
a third source electrode interposed in the first source electrode as viewed in the second direction, overlapping the second source electrode, and electrically connected to the first source electrode and the second source electrode;
a third drain electrode electrically connected to the first drain electrode and the second drain electrode; and
a third gate electrode interposed between the third source electrode and the third drain electrode in the first direction.

3. The semiconductor device according to claim 2, wherein the back metal layer is electrically connected to the third source electrode through a third via hole which overlaps the third source electrode when viewed in the thickness direction.

4. The semiconductor device according to claim 1, further comprising a fourth transistor provided on the main surface, the fourth transistor including:
a fourth source electrode disposed in the first source electrode when viewed from the second direction, the first gate wiring being interposed between the fourth source electrode and the second source electrode;
a fourth drain electrode provided between the fourth source electrode and the first gate wiring; and
a fourth gate electrode provided between the fourth source electrode and the fourth drain electrode in the first direction.

5. The semiconductor device according to claim 4, further comprising a fifth transistor provided on the main surface, the fifth transistor including the first source electrode, a fifth drain electrode electrically connected to the fourth drain electrode, and a fifth gate electrode interposed between the first source electrode and the fifth drain electrode in the first direction and electrically connected to the first gate wiring.

6. The semiconductor device according to claim 4, wherein the back metal layer is electrically connected to the fourth source electrode through a fourth via hole which overlaps the fourth source electrode when viewed in the thickness direction.

7. The semiconductor device according to claim 4, wherein
the semiconductor device has no via hole for electrically connecting the fourth source electrode and the back surface metal layer; and
a width of the fourth source electrode in the first direction is smaller than a width of the second source electrode in the first direction.

8. The semiconductor device according to claim 7, further comprising a wiring crossing the first gate wiring in a non-contact manner and connecting the second source electrode and the fourth source electrode.

9. The semiconductor device according to claim 1, further comprising:
a gate bus bar provided on the main surface and electrically connected to the second gate electrode and the first gate wiring; and
a drain bus bar provided on the main surface electrically connected to the first drain electrode and the second drain electrode, the first transistor and the second transistor being interposed between the gate bus bar and the drain bus bar in the second direction.

10. A semiconductor device comprising:
a substrate having a main surface and a back surface facing the main surface;
a first gate wiring provided on the main surface;
a first transistor provided on the main surface, the first transistor including a first drain electrode, a first gate electrode electrically connected to the first gate wiring, and a first source electrode, which are arranged in order in a first direction from the first gate wiring; and
a second transistor including a second drain electrode, a second gate electrode electrically connected to the first gate wiring, and a second source electrode, which are arranged in order from the first gate wiring in a direction opposite to the first direction, and which overlaps the first transistor when viewed from the first direction and is provided on the main surface.

11. The semiconductor device according to claim 10, further comprising a third transistor provided on the main surface, the third transistor including:
a third drain electrode which is arranged in order in the first direction and overlaps the first drain electrode when viewed from a second direction intersecting the first direction;
a third gate electrode electrically connected to the first gate wiring; and
a third source electrode which overlaps the first source electrode when viewed from the first direction.

12. The semiconductor device according to claim 11, further comprising:
a drain wiring connecting the first drain electrode and the third drain electrode; and
a second gate wiring which crosses the drain wiring in a non-contact manner between the first drain electrode and the third drain electrode and electrically connects the third gate electrode and the first gate wiring.

13. The semiconductor device according to claim 12, further comprising a first electrode provided between the first drain electrode and the third drain electrode on the main surface, provided between the second gate wiring and the first drain electrode or the third drain electrode, and supplied with a reference potential.

14. The semiconductor device according to claim 12, further comprising a second electrode provided on the main surface between the first gate wiring and the first drain electrode, and supplied with a reference potential.

15. The semiconductor device according to claim 10, further comprising a back metal layer provided on the back surface and electrically connected to the first source electrode and the second source electrode through a first via hole and a second via hole which overlap the first source electrode and the second source electrode, respectively, when viewed in the thickness direction of the substrate.

16. The semiconductor device according to claim 10, further comprising:
a gate bus bar provided on the main surface and electrically connected to the first gate electrode, the second gate electrode, and the first gate wiring; and
a drain bus bar provided on the main surface electrically connected to the first drain electrode and the second drain electrode, the first transistor and the second transistor being interposed between the gate bus bar and the drain bus bar in a second direction intersecting the first direction.
